(19) United States
(12) Patent Application Publication
(10) Pub. No.: US 2026/0040582 A1
(43) Pub. Date: Feb. 5, 2026

(54) MEMORY DIE BONDING IN STACKED SEMICONDUCTOR SYSTEMS

(71) Applicant: Micron Technology, Inc., Boise, ID (US)

(72) Inventors: Sui Chi Huang, Taichung (TW); Akshay N. Singh, Boise, ID (US); Bret K. Street, Meridian, ID (US)

(21) Appl. No.: 19/278,689

(22) Filed: Jul. 23, 2025

Related U.S. Application Data
(60) Provisional application No. 63/677,725, filed on Jul. 31, 2024.

(51) Int. Cl. H10B 80/00; H01L 25/00; H01L 25/065; H01L 25/18

(52) U.S. Cl. CPC H10B 80/00; H01L 25/0657; H01L 25/18; H01L 25/50; H01L 2225/06513; H01L 2225/06541; H01L 2225/06586

(57) ABSTRACT

Methods, systems, and devices for memory die bonding in stacked semiconductor systems are described. A semiconductor device may be formed to include a stack of memory dies. Each memory die of the stack may be bonded with at least one other memory die of the stack. The semiconductor device may include a dielectric material in contact with a portion of a first memory die of the stack, with the dielectric material extending beyond at least one lateral boundary of the first memory die of the stack. The semiconductor device may also include one or more molding materials formed over the stack of memory dies and over the dielectric material, with the one or more molding materials spanning a lateral dimension of the dielectric material and in contact with a portion of at least one memory die of the stack.

### CROSS REFERENCE

The present Application for Patent claims priority to U.S. Patent Application No. 63/677,725 by Huang et al., entitled “MEMORY DIE BONDING IN STACKED SEMICONDUCTOR SYSTEMS,” filed Jul. 31, 2024, which is assigned to the assignee hereof, and which is expressly incorporated by reference in its entirety herein.

### TECHNICAL FIELD

The following relates to one or more semiconductor systems, including memory die bonding in stacked semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports memory die bonding in stacked semiconductor systems in accordance with examples as disclosed herein.

FIG. 2 shows an example of a system that supports memory die bonding in stacked semiconductor systems in accordance with examples as disclosed herein.

FIGS. 3A through 3I illustrate examples of operations that support memory die bonding in stacked semiconductor systems in accordance with examples as disclosed herein.

FIGS. 4 and 5 show flowcharts illustrating a method or methods that support memory die bonding in stacked semiconductor systems in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., dynamic random access memory (DRAM) dies, array dies) or one or more stacks of memory dies that are coupled with a logic die (e.g., an interface die) that is operable to access a set of memory arrays distributed across the one or more memory dies. Such a stacked architecture may be implemented as part of a high bandwidth memory (HBM) system or a three-dimensional (3D) stacked memory system, among other examples, and may support solutions for memory-centric logic, such as graphics processing units (GPUs), among other implementations. In some examples, an HBM system may include one or more memory dies coupled with (e.g., bonded to, stacked on) a logic die.

In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die (with relevant circuitry), or may be formed with multiple die portions (e.g., relatively smaller dies, dies each including a respective subset of components of a logic unit) that may be referred to as “chiplets” (e.g., logic chiplets), among other examples.

Some techniques for fabricating stacked semiconductor systems (e.g., a semiconductor package, a semiconductor device) may include bonding a stack of memory dies with an interface die (e.g., a logic die). The interface die may provide an interface between the stack of memory dies and another system or device (e.g., a host system, a host device) and may facilitate operation of (and communication with) the memory dies of the stack (e.g., signaling operations, memory access operations, memory management operations, and other operations). Moreover, memory die stacks may be implemented in various applications, and each application may be associated with respective interface specifications (e.g., physical feature specifications, signaling specifications). Thus, specific interface dies may be designed and fabricated to accommodate each respective application of a memory die stack. However, fabrication of such semiconductor packages may include bonding a stack of memory dies with a unique (e.g., customized) interface die for a given application, which may not be adaptable for other applications. That is, unused (e.g., extra, surplus) semiconductor packages designed for one application may not be usable for other applications (e.g., may not satisfy interface expectations or specifications). Accordingly, such techniques of semiconductor system fabrication (e.g., that include bonding the interface die to the memory dies) may be relatively inefficient, resulting increased electronic waste and excessive manufacturing emissions.

In accordance with one or more techniques described herein, a semiconductor device may be fabricated (e.g., manufactured) to include one or more stacks of memory dies that are independent of an interface die (e.g., forming a “pre-stacked” memory device). In some examples, one or more first memory dies may be bonded to a carrier (e.g., a sacrificial carrier), and a dielectric material (e.g., a dielectric gap fill) may be formed around the first memory dies. Prior to bonding to the carrier, each memory die may be determined to be a known-good-die (KGD) (e.g., a die that satisfies an evaluation procedure), and forming the dielectric material may be associated with a wafer reconstruction of KGDs.

Additionally, one or more second memory dies may be subsequently bonded with the first memory dies to form one or more stacks of memory dies. In some additional, or alternative examples, a first stack of memory dies may be bonded with one or more second stacks of memory dies (e.g., to increase storage capacity). After forming the one or more memory die stacks, one or more molding materials may be formed over each stack, the carrier may be removed, and one or more contacts for making electrical connections with another device (e.g., an interface die) may be formed on the stack. Accordingly, the memory die stacks may be fabricated (e.g., and stored) separate from an interface die, which may support a subsequent bonding with different interface dies (e.g., or other devices). As such, semiconductor devices may be fabricated with improved efficiency, reduced waste, and reduced emissions, among other benefits.

In addition to applicability in memory systems as described herein, techniques for memory die bonding in stacked semiconductor systems may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and eliminating production processes, which may result in lowered production emissions and reduced electronic waste, among other benefits.

Features of the disclosure are illustrated and described in the context of systems and architectures. Features of the disclosure are further illustrated and described in the context of devices and flowcharts.

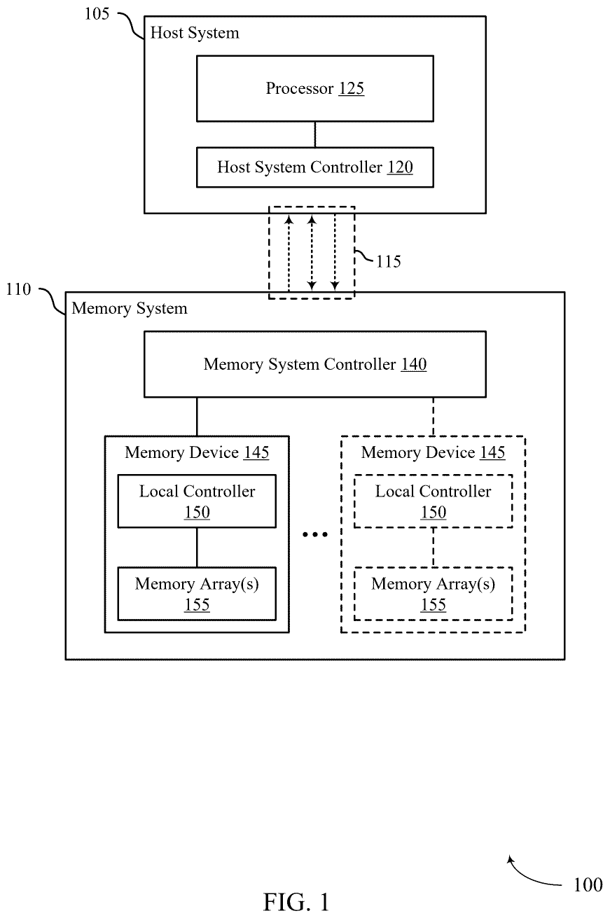

FIG. 1 shows an example of a system 100 that supports memory die bonding in stacked semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

Signals communicated over the channels 115 may be modulated using various modulation schemes or combinations thereof. A symbol of a binary-symbol (e.g., binary-level) modulation scheme may be operable to represent one bit of data (e.g., a symbol may represent a logic 1 or a logic 0), and may be an example of an M-ary modulation scheme where M is equal to two. Examples of binary-symbol modulation schemes include non-return-to-zero (NRZ), unipolar encoding, bipolar encoding, Manchester encoding, pulse amplitude modulation (PAM) having two symbols (e.g., PAM2), and others. A symbol of a multi-symbol modulation scheme may be operable to represent more than one bit of data (e.g., a symbol may represent a logic 00, a logic 01, a logic 10, or a logic 11), and may be an example of an M-ary modulation scheme where M is greater than or equal to three. For example, a multi-symbol signal may be modulated using a modulation scheme that includes at least three levels to encode more than one bit of information. Multi-symbol modulation schemes and symbols may be referred to as non-binary, multi-bit, or higher-order modulation schemes and symbols. Examples of multi-symbol modulation schemes include PAM3, PAM4, PAM8, and so on, quadrature amplitude modulation (QAM), quadrature phase shift keying (QPSK), and others.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies).

For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some fabrication techniques for forming a system 100 (e.g., a semiconductor device), or a memory system 110, may include bonding a stack of memory dies (e.g., including one or more memory devices 145, or a memory system 110) with an interface die. The interface die may serve facilitating communication with and operation of the memory dies of the stack (e.g., controller operations, signaling operations, memory access operations, memory management operations, and other operations). Moreover, memory die stacks may be implemented in various applications associated with respective interface specifications (e.g., in order to properly couple with a host system 105). Thus, specific interface dies may be designed for a respective application of a memory die stack. In some cases, fabrication of such memory systems 110 may include bonding a stack of memory dies with a unique (e.g., customized) interface die for a given application. However, unused (e.g., extra, surplus) systems 100, or memory system 110, designed for one application may not be usable for other applications (e.g., may not satisfy interface expectations or specifications), which may be relatively inefficient resulting increased electronic waste and excessive manufacturing emissions.

In accordance with techniques described herein, a memory system 110 may be fabricated (e.g., manufactured) to include one or more stacks of memory dies (e.g., memory device 145) that are independent of an interface die. In some examples, one or more first memory dies may be bonded to a carrier (e.g., a sacrificial carrier), and a dielectric material (e.g., a dielectric gap fill) may be formed around the first memory dies. Additionally, one or more second memory dies may be subsequently bonded with the first memory dies to form one or more stacks of memory dies. In some additional, or alternative examples, a first stack of memory dies may be bonded with one or more second stacks of memory dies (e.g., to increase storage capacity of the system 100). After forming the one or more memory die stacks, one or more molding compound materials may be formed over each stack, the carrier may be removed, and one or more contacts for making electrical connections with another device (e.g., an interface die) may be formed on the stack. Accordingly, a memory system 110 (e.g., a stacked memory system) may be fabricated (e.g., and stored) separate from an interface die, thus supporting a subsequent bonding with different interface dies (e.g., or other devices). As such, semiconductor devices may be fabricated with improved efficiency, reduced waste, and reduced emissions, among other benefits.

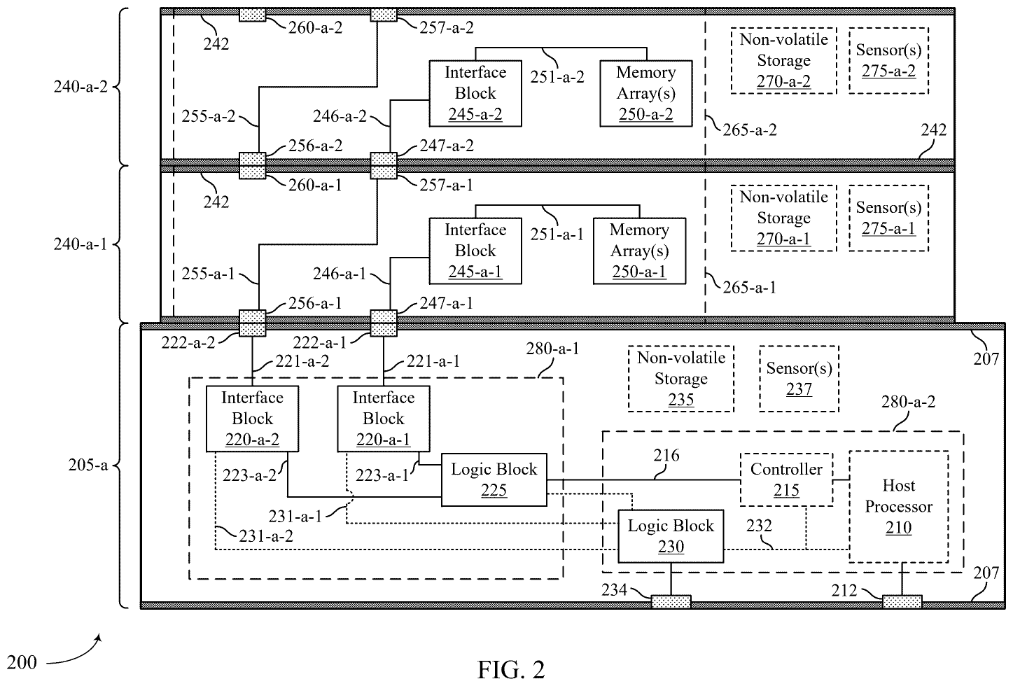

FIG. 2 shows an example of a system 200 (e.g., a semiconductor system, a system of coupled semiconductor dies, an HBM system, a 3D stacked memory system) that supports memory die bonding in stacked semiconductor systems in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout.

Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220.

Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255.

For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some fabrication techniques for forming a system 200 may include bonding a stack of dies 240 with a die 205. (e.g., an interface die). Stacks of dies 240 may be implemented in various applications associated with respective interface specifications. Thus, specific dies 205 may be designed for a respective application of a stack of dies 240. In some cases, fabrication of such systems 200 may include bonding a stack of dies 240 with a die 205 unique to a given application. However, unused (e.g., extra, surplus) systems 200 designed for one application may not be usable for other applications (e.g., may not satisfy interface expectations or specifications), which may be relatively inefficient resulting increased electronic waste and excessive manufacturing emissions.

In accordance with techniques described herein, a system 200 may be fabricated (e.g., manufactured) to include one or more stacks of dies 240 that are independent of a die 205. In some examples, one or more first dies 240 (e.g., a die 240-a-1) may be bonded to a carrier (e.g., a sacrificial carrier), and a dielectric material (e.g., a dielectric material 242) may be formed around the first dies 240. Additionally, one or more second dies 240 (e.g., a die 240-a-2) may be subsequently bonded with the first dies 240 to form one or more stacks of dies 240. In some additional, or alternative examples, a first stack of dies 240 may be bonded with one or more second stacks of dies 240 (e.g., to increase storage capacity of the system 200). After forming the one or more stacks, one or more molding compound materials may be formed over each stack of dies 240, the carrier may be removed, and one or more contacts (e.g., contacts 256, contacts 247, contacts 257, contacts 260) for making electrical connections with another device (e.g., an interface die) may be formed on the stack. Accordingly, a system 200 may be fabricated (e.g., and stored) separate from a die 205, thus supporting a subsequent bonding with different types of dies 205 (e.g., dies 205 that satisfy a different respective sets of specifications). As such, systems 200 may be fabricated with improved efficiency, reduced waste, and reduced emissions, among other benefits.

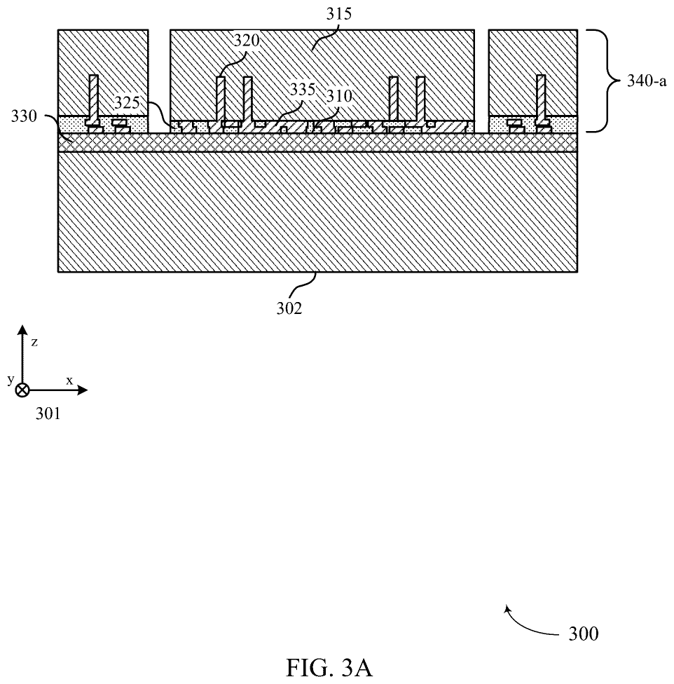

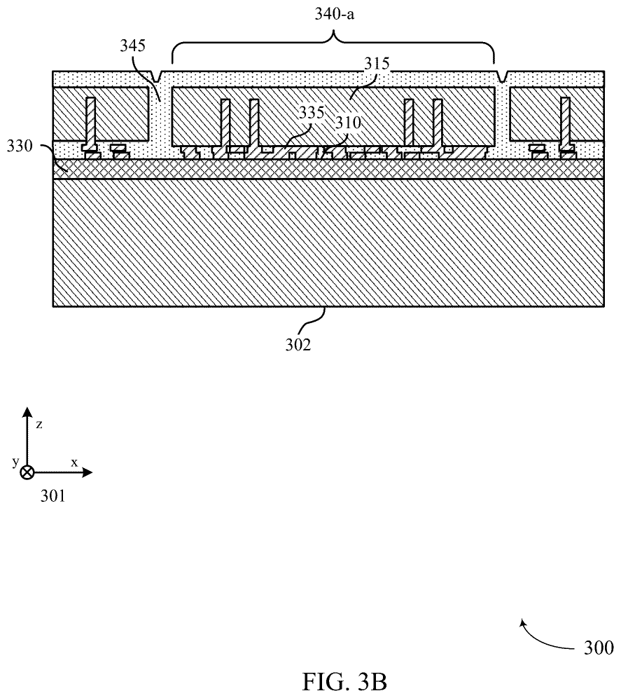

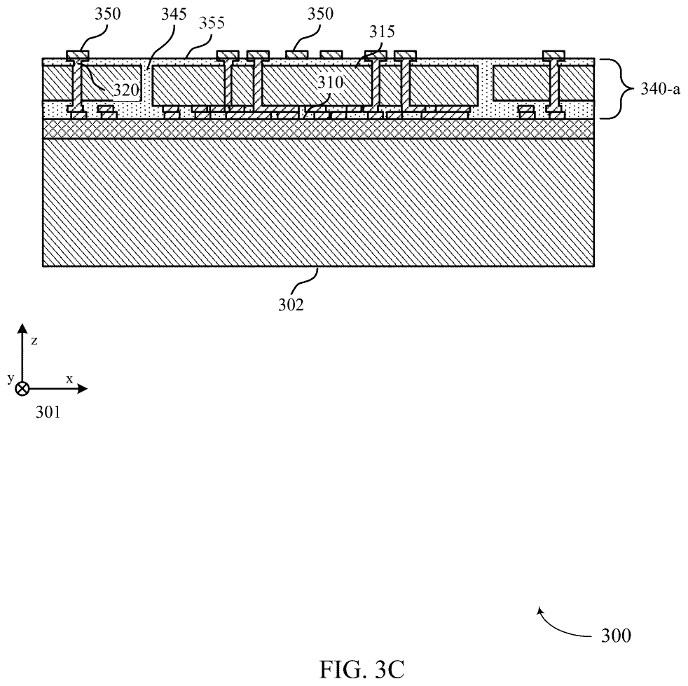

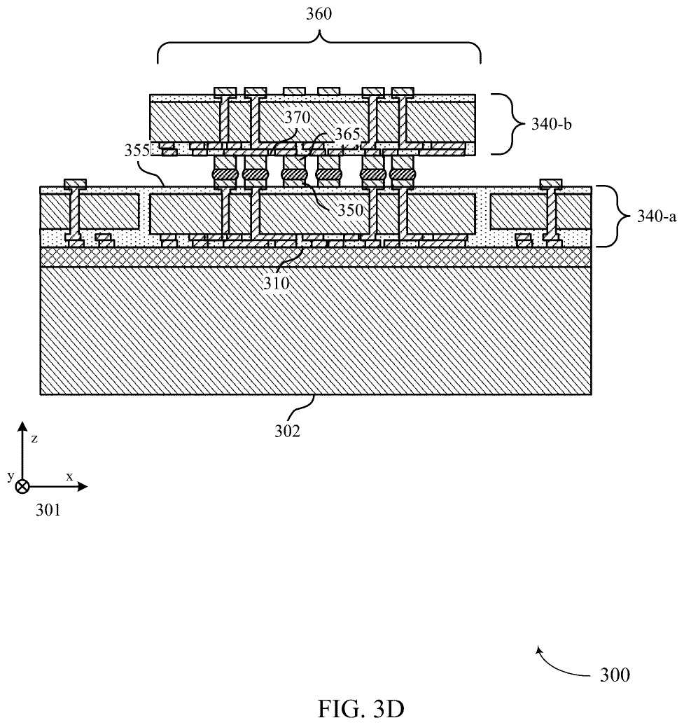

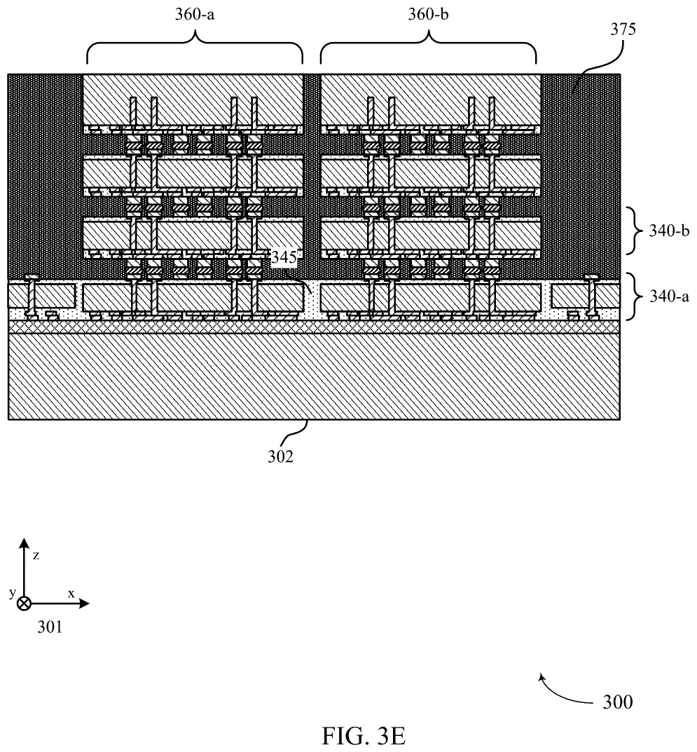

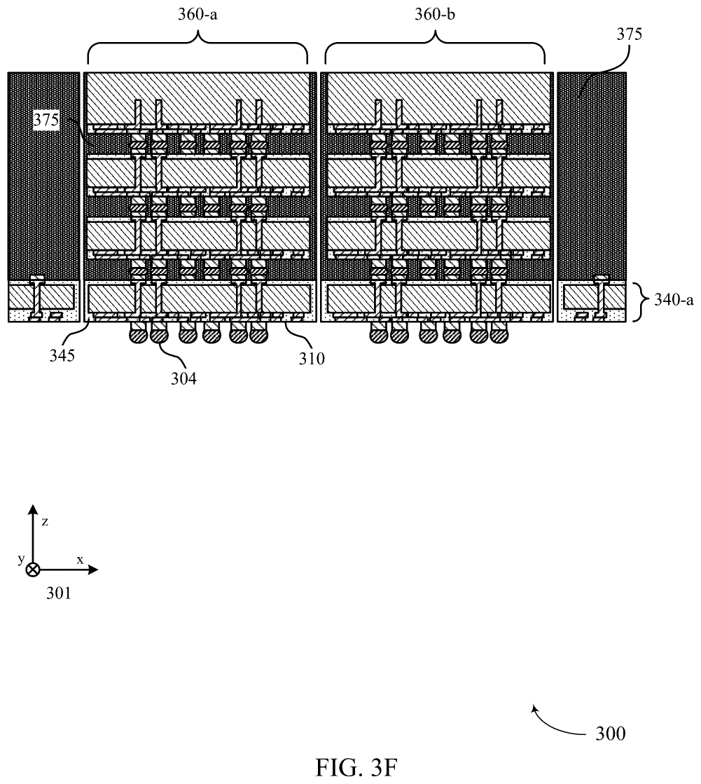

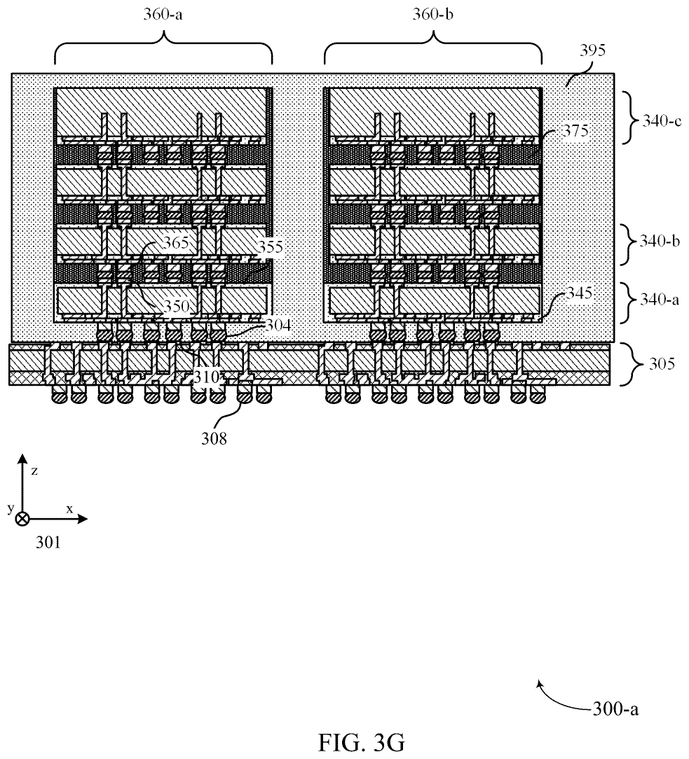

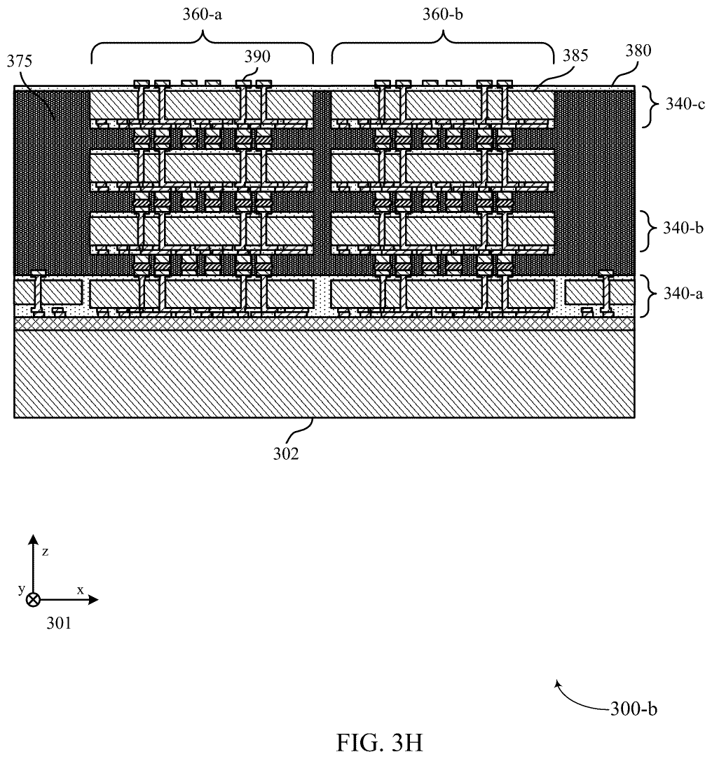

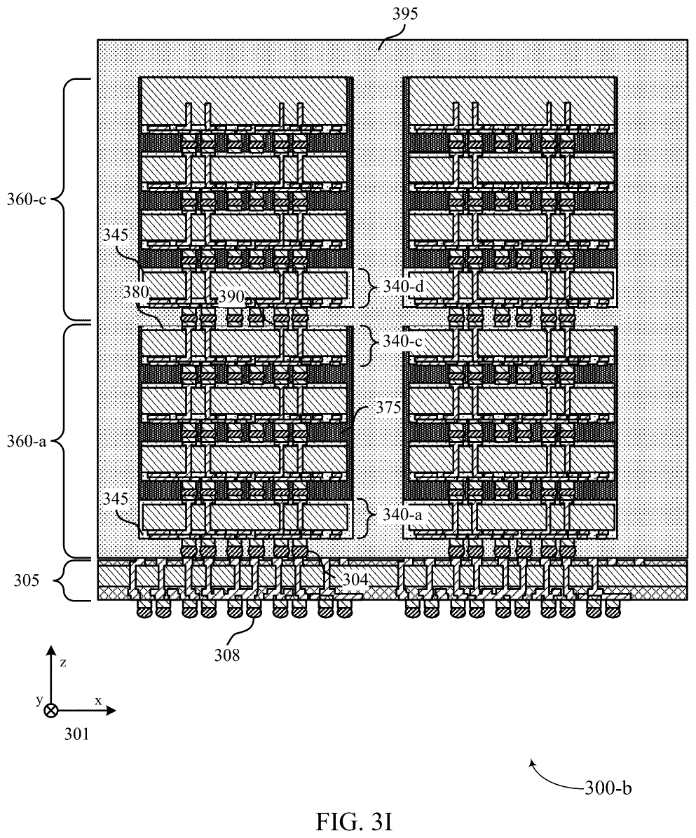

FIGS. 3A through 3I illustrate examples of operations that support memory die bonding in stacked semiconductor systems in accordance with examples as disclosed herein. Operations are illustrated with reference to a device 300, which may be an example of or include an electronic device (e.g., a semiconductor device, a system 100, a memory system 110, a host system 105, a system 200). For example, FIGS. 3A through 3I may illustrate aspects of a first sequence of operations that support manufacturing a system 100 or a portion thereof, a system 200 or a portion thereof, or some other device. Each of the figures may be described with reference to an x-direction, a y-direction, and a z-direction of a coordinate system 301. Operations illustrated in and described with reference to FIGS. 3A through 3I may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the device 300 that are illustrated with a same fill pattern may be formed of same or similar materials and portions that are illustrated with different patterns may be formed of different materials. Various dielectric materials are described herein. Each dielectric material may include a silicon oxide, silicon nitride, a silicon carbon nitride, a tetraethyl orthosilicate (TEOS), some other dielectric material, or any combination thereof. Additionally, conductive materials described herein may include copper, aluminum, tungsten, titanium, some other conductive material, or any combination thereof. In some examples, molding materials (e.g., mold compound materials) described herein may include epoxy-based materials (e.g., epoxy resin, thermoset materials, organic materials).

FIG. 3A shows an example of a cross-sectional view of the device 300 after a first set of one or more fabrication operations. For example, the first operations may include forming a carrier 302 (e.g., a semiconductor material carrier, a silicon carrier). The carrier may include a dielectric material 330, which may facilitate bonding (e.g., fusion bonding) with other dies. For example, the dielectric material 330 may include one or more alignment markings (e.g., fiducial markings, not shown) to support bonding to other dies. In some examples, the first operations may also include bonding (e.g., a face-down fusion bonding) a respective surface 310 of a set of one or more memory dies 340-a (e.g., dies 240, a memory device 145, memory array dies, bottom dies) to the carrier 302. In some examples, bonding the dies 340-a to the carrier 302 may be based on bonding a frontside of each die 340-a to a backside of the carrier 302 (e.g., based on a front-to-back bonding). In some examples, the first operations may include determining that each die 340-a satisfies an evaluation procedure prior to bonding on the carrier 302 (e.g., to support a reconstruction of KGDs).

Each die 340-a may include a respective substrate 315 (e.g., substrate material, semiconductor substrate, semiconductor substrate portion, silicon material) and may be formed with one or more vias 320 (e.g., through silicon vias (TSVs)). The vias 320 may be formed of one or more conductive materials (e.g., formed by one or more cavities filled with conductive material). Semiconductor substrate materials described herein may include memory array circuitry, interconnection circuitry, or other circuitry. Each die 340-a may include a dielectric material 325, which may facilitate the bond (e.g., a fusion bond) with a dielectric material 330 formed at a surface of the carrier 302. In some examples, the dielectric material 325 may further include one or more conductors 335 (e.g., bond pads, traces, alignment markings), which may further facilitate the bond with the carrier 302. In some examples, the first operations may further include formation (e.g., customization) of a redistribution layer (RDL) associated with the dies 340-a.

FIG. 3B shows an example of a cross-sectional view of the device 300 after a second set of one or more fabrication operations. For example, the second operations may include removing (e.g., thinning, grinding, cutting) a portion of the respective substrates 315 (e.g., to meet a height expectation along the z-direction). The second operations may also include forming a dielectric material 345 (e.g., a gap filling material, TEOS) between and over each of the memory dies 340-a and over the carrier 302. In some examples, the dielectric material 345 may extend beyond respective lateral boundaries of each memory die 340-a.

FIG. 3C shows an example of a cross-sectional view of the device 300 after a third set of one or more fabrication operations. For example, the third operations may include forming (e.g., after forming the dielectric material 345) a set of one or more contacts 350 (e.g., pads, pillars, bumps). In some examples, the contacts 350 may be formed based on a plating operation. As described herein, “plating” may refer to a process in which a layer of conductive material (e.g., metal) is deposited onto the surface of a device (e.g., the dielectric material 345, the respective substrates 315). In some examples, plating may include electroplating techniques (e.g., using an electric current to reduce dissolved metal cations onto the device) and/or electroless plating (e.g., a chemical reaction to achieve the conductive coating).

The contacts 350 may be formed of one or more conductive materials and may be formed at each respective surface 355 (e.g., opposite the surface 310) of the dies 340-a. In some examples, the contacts 350 may facilitate a bond between the dies 340-a and one or more other dies. That is, bonding other dies to the respective surfaces 355 may be based on forming the contacts 350. The third operations may also include forming an additional portion of the one or more vias 320 (e.g., to reveal the TSVs at the surface 355), which may facilitate a coupling between the contacts 350 and the vias 320. In some examples, the dielectric material 345, or at least a portion thereof, may not be formed. In such examples, the one or more vias 320 may be revealed and the one or more contacts 350 may be formed prior to bonding the dies 340-a with the carrier 302.

FIG. 3D shows an example of a cross-sectional view of the device 300 after a fourth set of one or more fabrication operations. For example, the fourth operations may include forming one or more stacks 360 (e.g., DRAM cubes) of memory dies 340 (e.g., above the dies 340-a). Forming the stacks 360 may be based on bonding one or more memory dies 340-b to the respective surfaces 355 (e.g., opposite the surfaces 310) of the dies 340-a. In some examples, bonding the dies 340-b to the dies 340-a may be based on bonding (e.g., via a solder bond) the contacts 350 with one or more contacts 365 (e.g., pads, pillars, bumps, formed of conductive material) formed at respective surfaces 370 of the dies 340-b. Additionally, or alternatively, the dies 340-b may be bonded with the dies 340-a based on a hybrid bonding (e.g., a dielectric material bonding and a conductive material bonding). In such examples, the surfaces 370 may be in direct contact with the surfaces 355. In some examples, the fourth operations may also include determining that each die 340-b dies satisfies an evaluation procedure prior to bonding to the die 340-a (e.g., to support a reconstruction of KGDs).

FIG. 3E shows an example of a cross-sectional view of the device 300 after a fifth set of one or more fabrication operations. For example, the fifth operations may include repeating one or more bonding operations herein (e.g., as described with reference to FIG. 3D) to form a stack 360 of multiple (e.g., three or more) dies 340. The fifth operations may also include forming (e.g., after stacking or bonding the dies 340) one or more molding materials 375 between and over each stack 360 (e.g., the stack 360-a and the stack 360-b) of dies 340. The one or more molding materials 375 may also be formed over the dielectric material 345. In some examples, the molding materials 375 may span a lateral dimension (e.g., along the x-direction) of the dielectric material 345 and may be in contact with a portion of at least one die 340 (e.g., a die 340-b).

In some examples, forming the molding materials 375 may include an underfilling operation and a molding operation (e.g., a molding and underfilling (MUF) operation). For example, the underfilling operation may include forming an underfilling material (e.g., a first molding material) between each of the dies 340. The underfilling operation may be followed by the molding operation, which may including forming a mold compound material (e.g., a second molding material) over the underfilling material. Thus, the molding materials 375 may include multiple types of molding materials that are used to cover (e.g., coat, surround, protect) the dies 340. Alternatively, the molding materials 375 may include a single type of mold compound material, which may cover the dies 340.

FIG. 3F shows an example of a cross-sectional view of the device 300 after a sixth set of one or more fabrication operations. For example, the sixth operations may include removing the carrier 302 to expose the respective surfaces 310 of the memory dies 340-a. The sixth operations may include forming, at the respective surfaces 310, one or more contacts 304 (e.g., solder balls, bumps, pads, pillars) with a conductive material (e.g., by performing a plating operation). The one or more contacts 304 may be associated with (e.g., may be formed for) making electrical connections with one or more other semiconductor dies (e.g., an interface die, a logic die). The sixth operations make also include removing (e.g., etching, cutting, dicing) a portion of the molding materials 375 and a portion of the dielectric material 345. Accordingly, each stack 360 of dies 340 may be separated (e.g., singulated) from other stacks 360 of dies 340 based on removing the portion of the molding materials 375 and the portion of the dielectric material 345. For example, the stack 360-a and the stack 360-b may be physically separated based on the removal operations.

In some examples, the fabrication process may terminate at this stage based on the formation of independent stacks 360 (e.g., a standalone DRAM cube). For example, a device 300 may include a single stack 360 of dies 340. Each stack 360 may include a set of dies 340, one or more molding materials 375 in contact with (e.g., surrounding) one or more dies 340, and one or more contacts 304 that support a bond with other semiconductor devices, such as a logic die (e.g., a die 205), an interface die, or an interface wafer, among other examples. Additionally, each stack 360 may include any quantity of dies 340, including more or fewer dies 340 than shown. Accordingly, a stack 360 of dies 340 may support bonding with various interface dies supporting a variety of different applications, thus increasing storage flexibility.

FIG. 3G shows an example of a cross-sectional view of the device 300 after a seventh set of one or more fabrication operations, which may be optional. For example, the seventh operations may include bonding (e.g., after removing the portion of the molding materials 375 and the portion of the dielectric material 345, after singulation of the stacks 360) one or more stacks 360 with a die 305 (e.g., a substrate, an interface die, a logic die, a semiconductor die, a die 205). The die 305 may include one or more contacts 308 for making electrical connections with other systems or devices (e.g., a host system 105, a CPU, a GPU). In some examples, the seventh set of operations may include forming one or more molding materials 395 over the molding materials 375 (e.g., in accordance with a MUF operation or a single molding operation). The molding materials 395 may span a lateral dimension (e.g., along the x-direction) of the die 305 and may be in contact with a portion of the dielectric material 345. The molding materials 395 may be formed over one or more stacks 360 that already have molding materials 375.

Accordingly, by applying one or more techniques described herein, a device 300-a may be manufactured to include a stack 360 of memory dies 340. Each die 340 of the stack 360 may be bonded with at least one other die 340 of the stack 360. The device 300-a may also include a dielectric material 345 that is in contact with a portion of a first memory die (e.g., a die 340-a) of the stack 360, and the dielectric material 345 may extend beyond at least one lateral boundary of the first memory die. The device 300-a may also include one or more molding materials 375 formed over the stack 360 and over the dielectric material 345. In some examples, the device 300-a may additionally include one or more molding materials 395 formed over the one or more molding materials 375. In some examples, at least one die 340 (e.g., a die 340-a, a bottom die) of the stack 360 may be surrounded by the dielectric material 345, and one or more other dies 340 (e.g., a die 340-b, a die 340-c, a top die) of the stack 360 may be surrounded by the molding materials 375.

The device 300-a may include a set of multiple of contacts 304 formed at a surface 310 of the first memory die of the stack 360, which may be for making electrical connections with one or more other semiconductor dies. The first die 340 may be bonded with a second die 340 (e.g., a die 340-b) of the stack at a surface 355 of the first die that is opposite the surface 310. In some examples, the device 300-a may include a substrate bonded with (e.g., or above) a die 340-c of the stack 360 (e.g., to achieve a target height in the z-direction), and the die 340-c may be located at an opposite end of the device 300-a as the first memory die (e.g., the die 340-a). In some instances, FIG. 3G may illustrate a process where the die 340-c is reconstructed on a known-good top DRAM die reconstructed wafer (e.g., a C2W/S2 W process). In some examples, a die 340-c may include one or more unrevealed vias. In some examples, each die 340 of the stack 360 may be bonded with at least one other die 340 of the stack based on a set of multiple of contacts (e.g., solder ball connections, micro bump connections, one or more contacts 350, one or more contacts 365). In some examples, the stack 360 of dies 340 may include three or more dies 340.

In some examples, the device 300-a may also include a die 305 bonded with one or more stacks 360. The die 305 may include circuitry operable to facilitate one or more access operations on the dies 340 of the stack 360. In such examples, the one or more molding materials 395 may be formed over the die 305 and may span a lateral dimension (e.g., along the x-direction) of the die 305.

FIG. 3H shows an example of a cross-sectional view of an device 300-b (e.g., an additional or alternate example of a device 300) after an eighth set of one or more fabrication operations. At least some of the operations of the eighth set may be optional (e.g., and may not be performed in some cases). In some examples, the eighth set of operations may be additionally, or alternatively, performed after the fifth set of operations (e.g., as described with reference to FIG. 3E, skipping at least a portion of the sixth operations and/or the seventh operations). For example, the eighth operations may include fabrication techniques to support bonding a second stack (not shown) of dies 340 to (e.g., over, on top of) one or more stacks 360 (e.g., stack 360-a, stack 360-b).

The eighth operations may include forming, prior to bonding a second stack of dies 340 (e.g., an after formation of the molding materials 375), a dielectric material 380 over a surface 385 of a respective die 340-c (e.g., a top die in a stack 360) and over the molding materials 375. The formation of the dielectric material 380 may be associated with a passivation process (e.g., a backside passivation), where “passivation” may refer to a deposition of a protective layer over a material (e.g., to protect the surface 385, to mitigate undesired electrical conductivity). In some examples, the dielectric material 380 may be in contact with a portion of the molding materials 375 and may span a lateral dimension (e.g., along the x-direction) of the molding materials 375. The eighth operations may also include forming, at the surfaces 385 of the memory dies 340-c, one or more contacts 390 for making electrical connections with one or more other semiconductor dies. In some examples, bonding a second stack (not shown) of dies 340 to a stack 360 may be based on forming the contacts 390.

In other words, based on forming the dielectric material 380 and the one or more contacts 390, the eighth operations may prepare the device 300 to support a bonding of a second stack of dies 340 to a stack 360 of memory dies 340. Such bonding may be based on bonding a respective die 340 of the second stack to a respective die 340-c of a stack 360. The respective die 340 of the second stack may include a dielectric material that spans a lateral dimension of the respective die 340. In some examples, the eighth operations may also include determining that each die 240 of the second stack satisfies an evaluation procedure prior to bonding with a stack 360 (e.g., to support a reconstruction of KGDs).

In some examples, the eighth operations may also include bonding (e.g., a fusion bonding, after forming the dielectric material 380, the one or more contacts 390, or both) a substrate (e.g., a silicon substrate) with the device 300 (e.g., on top of the dielectric material 380 and the contacts 390, with the surfaces 385), which may extend a height dimension of the device 300 (e.g., along a z-direction, to achieve a desired overall thickness along the z-direction). In some examples, such a substrate may include a layer of dielectric material at a bonding surface to support bonding with the device 300.

FIG. 3I shows an example of a cross-sectional view of the device 300 after a ninth set of one or more fabrication operations. In some examples, the ninth operations may follow the eighth operations (e.g., if performed). The ninth operations may include bonding a stack 360-c of dies 340 (e.g., formed in accordance with one or more techniques described herein) to the stack 360-a of memory dies by bonding a die 340-d of the stack 360-c to a die 340-c of the stack 360-a. In some instances, FIG. 3I may illustrate a process where the stack 360-c is reconstructed on a known-good core DRAM die reconstructed wafer (e.g., a C2W/S2 W process). In some examples, the die 340-d may include a dielectric material 345 that spans a lateral dimension of the die 340-d. In some examples, the ninth operations may include forming one or more molding materials 395 (e.g., in accordance with a MUF operation or a single molding operation) between and over each stack 360 (e.g., the stack 360-c and the stack 360-a). In some examples, the one or more molding materials 395 may be in contact with the molding materials 375 of the stack 360-a and the molding materials 375 of the stack 360-c and extending beyond a lateral dimension of the respective dielectric materials 345. In some examples, the molding materials 395 may also be in contact with the dielectric material 380 (e.g., a backside passivation layer may be in contact with the molding materials 395).

Accordingly, by applying one or more techniques described herein, a device 300-b may be manufactured to include a first stack 360 (e.g., a stack 360-a) including a first set of dies 340 that are each bonded with at least one other die 340 in the first stack 360. The device 300-b may also include a first dielectric material 345 in contact with a portion of a first die (e.g., a die 340-a, a first die 340 surrounded by gap fill material) of the first stack 360, and the first dielectric material 345 may extend beyond each lateral boundary of the first die. The device 300-b may include a second stack 360 (e.g., a stack 360-c) that includes a second set of dies 340 that are each bonded with at least one other die 340 in the second stack 360. A first die 340 (e.g., a die 340-d, a second die 340 surrounded by gap fill material) of the second stack 360 may be bonded with a second die (e.g., a die 340-c) of the first stack 360. The device 300-b may further include a second dielectric material 345 in contact with a portion of the first die 340 of the second stack 360, and the second dielectric material 345 may extend beyond each lateral boundary of the first die of the second stack.

In some examples, the device 300-b may include a dielectric material 380 (e.g., backside passivation layer) formed over a surface of the second die (e.g., the die 340-c) of the first stack 360 and over the one or more molding materials 375 of the first stack 360. The device 300-b may also include one or more first molding materials 375 formed over the first stack 360. Additionally, the device 300-b may include one or more second molding materials 375 formed over the second stack 360. The device 300-b may also include one or more molding materials 395 (e.g., a double molding formation) formed between and over the first stack 360 and the second stack 360.

In some examples, the device 300-b may include a set of multiple of contacts 390 for making electrical connections. The contacts 390 may be formed at a surface of the second die (e.g., the die 340-c) of the first stack 360, and a bond between the second stack 360 and the first stack 360 may be formed based on the set of multiple of contacts 390. Additionally, or alternatively, the device 300-b may include a set of multiple of contacts 304 for making electrical connections with one or more other semiconductor dies, such as a die 305 (e.g., an interface substrate, a logic die, a die 205). In some examples, the device 300-b may also include a die 305 bonded with one or more stacks 360, and the die 305 may include one or more contacts 308 for making electrical connections with other systems or devices (e.g., a host system 105, a CPU, a GPU). The die 305 may include circuitry operable to facilitate one or more access operations on the dies 340 of the stacks 360. In such examples, the one or more molding materials 395 may be formed over the die 305 and may span a lateral dimension (e.g., along the x-direction) of the die 305.

Accordingly, by implementing one or more techniques herein, various devices 300 may be manufactured with increased storage flexibility based on improved versatility and on improved structural integrity (e.g., provided by the formation of molding materials). Moreover, a device 300 may support increased application flexibility (e.g., for different customized interface substrates, customized memory stacks) based on being fabricated independently of a die 305. The described techniques may further provide for increased capacity, enabling a device 300 to satisfy increased storage capacity expectations. Further, each die 340 may be evaluated prior to bonding operations (e.g., based intermediate opportunities for performance of an evaluation procedure), which may improve a reliability of a device 300.

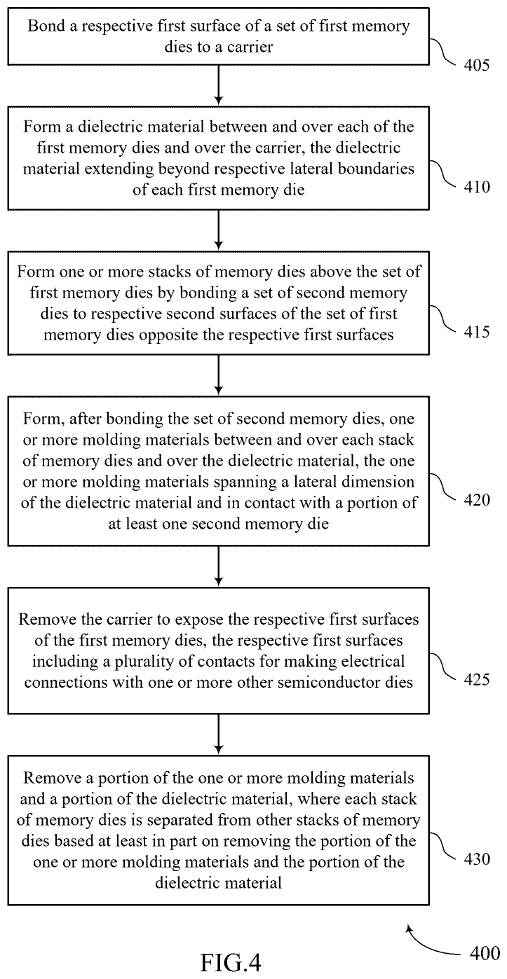

FIG. 4 shows a flowchart illustrating a method or methods 400 that support memory die bonding in stacked semiconductor systems in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include bonding a respective first surface of a set of first memory dies to a carrier.

At 410, the method may include forming a dielectric material between and over each of the first memory dies and over the carrier, the dielectric material extending beyond respective lateral boundaries of each first memory die.

At 415, the method may include forming one or more stacks of memory dies above the set of first memory dies by bonding a set of second memory dies to respective second surfaces of the set of first memory dies opposite the respective first surfaces.

At 420, the method may include forming, after bonding the set of second memory dies, one or more molding materials between and over each stack of memory dies and over the dielectric material, the one or more molding materials spanning a lateral dimension of the dielectric material and in contact with a portion of at least one second memory die.

At 425, the method may include removing the carrier to expose the respective first surfaces of the first memory dies, the respective first surfaces including a plurality of contacts for making electrical connections with one or more other semiconductor dies.

At 430, the method may include removing a portion of the one or more molding materials and a portion of the dielectric material, where each stack of memory dies is separated from other stacks of memory dies based at least in part on removing the portion of the one or more molding materials and the portion of the dielectric material.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding a respective first surface of a set of first memory dies to a carrier; forming a dielectric material between and over each of the first memory dies and over the carrier, the dielectric material extending beyond respective lateral boundaries of each first memory die; forming one or more stacks of memory dies above the set of first memory dies by bonding a set of second memory dies to respective second surfaces of the set of first memory dies opposite the respective first surfaces; forming, after bonding the set of second memory dies, one or more molding materials between and over each stack of memory dies and over the dielectric material, the one or more molding materials spanning a lateral dimension of the dielectric material and in contact with a portion of at least one second memory die; removing the carrier to expose the respective first surfaces of the first memory dies, the respective first surfaces including a plurality of contacts for making electrical connections with one or more other semiconductor dies; and removing a portion of the one or more molding materials and a portion of the dielectric material, where each stack of memory dies is separated from other stacks of memory dies based at least in part on removing the portion of the one or more molding materials and the portion of the dielectric material.

Aspect 2: The method or apparatus of aspect 1, further including operations, features, circuitry, logic, means, or instructions, or any combination thereof for bonding, after removing the portion of the one or more molding materials and the portion of the dielectric material, a first stack of the one or more stacks of memory dies with a substrate of a semiconductor die and forming one or more second molding materials over the one or more molding materials, the one or more second molding materials spanning a lateral dimension of the substrate and in contact with a portion of the dielectric material.

Aspect 3: The method or apparatus of any of aspects 1 through 2, further including operations, features, circuitry, logic, means, or instructions, or any combination thereof for forming, after removing the carrier and before removing the portion of the one or more molding materials and the portion of the dielectric material, the plurality of contacts of the respective first surfaces with one or more conductive materials.

Aspect 4: The method or apparatus of any of aspects 1 through 3, further including operations, features, circuitry, logic, means, or instructions, or any combination thereof for forming, after forming the dielectric material, a plurality of second contacts of the respective second surfaces with one or more conductive materials, where bonding the set of second memory dies to the respective second surfaces is based at least in part on forming the plurality of second contacts.

Aspect 5: The method or apparatus of aspect 4, where bonding the set of second memory dies to the respective second surfaces includes operations, features, circuitry, logic, means, or instructions, or any combination thereof for bonding the plurality of second contacts with a plurality of third contacts formed at a respective first surfaces of the set of second memory dies.

Aspect 6: The method or apparatus of any of aspects 1 through 5, further including operations, features, circuitry, logic, means, or instructions, or any combination thereof for bonding, after forming the one or more molding materials, respective second surfaces of the set of second memory dies with a substrate to extend a height dimension of the semiconductor device.

Aspect 7: The method or apparatus of any of aspects 1 through 6, further including operations, features, circuitry, logic, means, or instructions, or any combination thereof for determining that each first memory die of the set of first memory dies satisfies an evaluation procedure prior to bonding on the carrier.

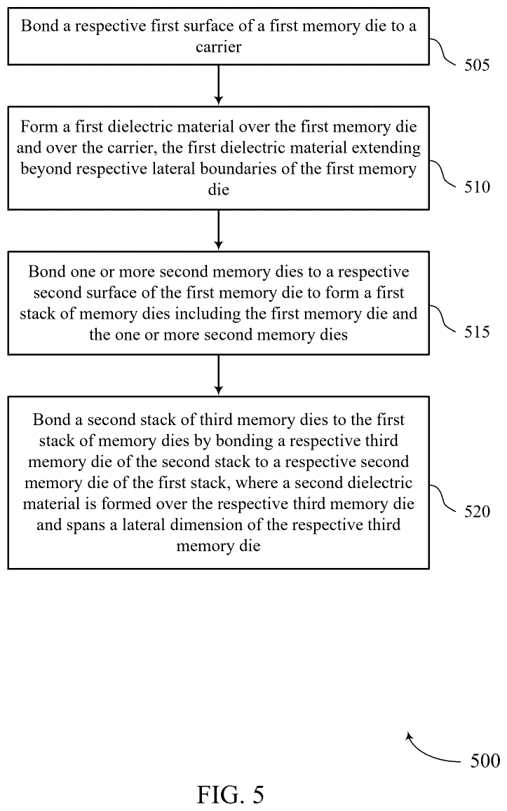

FIG. 5 shows a flowchart illustrating a method or methods 500 that support memory die bonding in stacked semiconductor systems in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include bonding a respective first surface of a first memory die to a carrier.

At 510, the method may include forming a first dielectric material over the first memory die and over the carrier, the first dielectric material extending beyond respective lateral boundaries of the first memory die.

At 515, the method may include bonding one or more second memory dies to a respective second surface of the first memory die to form a first stack of memory dies including the first memory die and the one or more second memory dies.

At 520, the method may include bonding a second stack of third memory dies to the first stack of memory dies by bonding a respective third memory die of the second stack to a respective second memory die of the first stack, where a second dielectric material is formed over the respective third memory die and spans a lateral dimension of the respective third memory die.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 8: A method or apparatus including operations, features, circuitry, logic, means, or instructions, or any combination thereof for bonding a respective first surface of a first memory die to a carrier; forming a first dielectric material over the first memory die and over the carrier, the first dielectric material extending beyond respective lateral boundaries of the first memory die; bonding one or more second memory dies to a respective second surface of the first memory die to form a first stack of memory dies including the first memory die and the one or more second memory dies; and bonding a second stack of third memory dies to the first stack of memory dies by bonding a respective third memory die of the second stack to a respective second memory die of the first stack, where a second dielectric material is formed over the respective third memory die and spans a lateral dimension of the respective third memory die.

Aspect 9: The method or apparatus of aspect 8, further including operations, features, circuitry, logic, means, or instructions, or any combination thereof for forming, after bonding the one or more second memory dies, one or more first molding materials between and over the first memory die and the one or more second memory dies, the one or more first molding materials in contact with a portion of the first dielectric material and spanning a lateral dimension of the first dielectric material.

Aspect 10: The method or apparatus of aspect 9, further including operations, features, circuitry, logic, means, or instructions, or any combination thereof for forming one or more second molding materials between and over each of the third memory dies of the second stack, the one or more second molding materials in contact with a portion of the second dielectric material and spanning a lateral dimension of the second dielectric material.

Aspect 11: The method or apparatus of aspect 10, further including operations, features, circuitry, logic, means, or instructions, or any combination thereof for forming one or more third molding materials between and over the first stack and the second stack, the one or more third molding materials in contact with the one or more first molding materials and the one or more second molding materials and extending beyond a lateral dimension of the first dielectric material and the second dielectric material.

Aspect 12: The method or apparatus of any of aspects 9 through 11, further including operations, features, circuitry, logic, means, or instructions, or any combination thereof for forming, prior to bonding the second stack of third memory dies, a third dielectric material over a second surface of a respective second memory die and over the one or more first molding materials, the third dielectric material in contact with a portion of the one or more first molding materials and spanning a lateral dimension of the one or more first molding materials and forming, at a second surface of the respective second memory dies, a plurality of contacts for making electrical connections with one or more other semiconductor dies, where bonding the second stack to the first stack is based at least in part on forming the plurality of contacts.

Aspect 13: The method or apparatus of any of aspects 8 through 12, further including operations, features, circuitry, logic, means, or instructions, or any combination thereof for removing the carrier to expose the first surface of the first memory die and forming a plurality of contacts with one or more conductive materials at the first surface, the plurality of contacts for making electrical connections with one or more other semiconductor dies.

Aspect 14: The method or apparatus of any of aspects 8 through 13, further including operations, features, circuitry, logic, means, or instructions, or any combination thereof for determining that the first memory die satisfies an evaluation procedure prior to bonding with the carrier, that the one or more second memory dies satisfy the evaluation procedure prior to bonding to the first memory die, and that each of the third memory dies satisfy the evaluation procedure prior to bonding with the first stack.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: A semiconductor device, including: a stack of memory dies, where each memory die of the stack is bonded with at least one other memory die of the stack; a dielectric material in contact with a portion of a first memory die of the stack, the dielectric material extending beyond at least one lateral boundary of the first memory die of the stack; and one or more molding materials formed over the stack of memory dies and over the dielectric material, the one or more molding materials spanning a lateral dimension of the dielectric material and in contact with a portion of at least one memory die of the stack.

Aspect 16: The semiconductor device of aspect 15, further including: one or more second molding materials formed over the one or more molding materials.

Aspect 17: The semiconductor device of any of aspects 15 through 16, further including: a plurality of contacts formed at a first surface of the first memory die of the stack, the plurality of contacts for making electrical connections with one or more other semiconductor dies.

Aspect 18: The semiconductor device of aspect 17, where the first memory die is bonded with a second memory die of the stack at a second surface of the first memory die that is opposite the first surface.

Aspect 19: The semiconductor device of any of aspects 15 through 18, further including: a substrate bonded with a second memory die of the stack of memory dies, the second memory die located at an opposite end of the semiconductor device as the first memory die.

Aspect 20: The semiconductor device of any of aspects 15 through 19, where each memory die of the stack is bonded with at least one other memory die of the stack by a first plurality of contacts.

Aspect 21: The semiconductor device of any of aspects 15 through 20, where the stack of memory dies includes three or more memory dies.

An apparatus is described. The following provides an overview of aspects of the apparatus as described herein:

Aspect 22: A semiconductor device, including: a first stack including a first plurality of memory dies, each memory die of the first stack bonded with at least one other memory die in the first stack; a first dielectric material in contact with a portion of a first memory die of the first stack, the first dielectric material extending beyond each lateral boundary of the first memory die of the stack; a second stack including a second plurality of memory dies, each memory die of the second stack bonded with at least one other memory die in the second stack, a first memory die of the second stack being bonded with a second memory die of the first stack; and a second dielectric material in contact with a portion of the first memory die of the second stack, the second dielectric material extending beyond each lateral boundary of the first memory die of the second stack.

Aspect 23: The semiconductor device of aspect 22, further including: one or more first molding materials formed over the first stack, the one or more first molding materials spanning a lateral dimension of the first dielectric material and in contact with a portion of at least one memory die of the first stack.

Aspect 24: The semiconductor device of aspect 23, further including: one or more second molding materials formed over the second stack, the one or more second molding materials spanning a lateral dimension of the second dielectric material and in contact with a portion of at least one memory die of the second stack.

Aspect 25: The semiconductor device of aspect 24, further including: one or more third molding materials formed between and over the first stack and the second stack, the one or more third molding materials in contact with the one or more first molding materials and the one or more second molding materials and extending beyond a lateral dimension of the first dielectric material and the second dielectric material.

Aspect 26: The semiconductor device of any of aspects 23 through 25, further including: a third dielectric material formed over a surface of the second memory die of the first stack and over the one or more first molding materials, the third dielectric material spanning a lateral dimension of the one or more first molding materials.

Aspect 27: The semiconductor device of any of aspects 22 through 26, further including: a plurality of contacts for making electrical connections, the plurality of contacts formed at a surface of the second memory die of the first stack, where a bond between the second stack and the first stack is formed using the plurality of contacts.

Aspect 28: The semiconductor device of any of aspects 22 through 27, further including: a plurality of contacts for making electrical connections with one or more other semiconductor dies formed at a surface of the first memory die of the first stack.

An apparatus is described. The following provides an overview of aspects of the apparatus as described herein:

Aspect 29: A semiconductor device, including: a stack of memory dies, where each memory die of the stack is bonded with at least one other memory die of the stack; a first dielectric material in contact with a portion of a first memory die of the stack, and the first dielectric material extending beyond each lateral boundary of the first memory die of the stack; one or more first molding materials formed over the stack and over the first dielectric material, the one or more first molding materials spanning a lateral dimension of the first dielectric material and in contact with a portion of at least one memory die of the stack; a logic die bonded with a first side of the first memory die opposite a second side of the first memory die, the logic die including circuitry operable to facilitate one or more access operations on the memory dies of the stack; and one or more second molding materials formed over the first molding materials and over the logic die, the one or more second molding materials spanning a lateral dimension of the logic die.

Aspect 30: The semiconductor device of aspect 29, further including: a plurality of contacts for making electrical connections formed at the first side of the first memory die, where the first memory die is bonded to the logic die by the plurality of contacts.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

Some examples and operations described herein may be described with reference to various sides of a respective component. For example, a side of a component may be referred to as a “backside” or “back,” or a “frontside” or “front.” A frontside of a semiconductor device may refer to a side that includes components such as transistors and capacitors. The frontside may also include an electrically conductive metallization structure with chip contact areas. The frontside may include front end of line (FEOL), middle of line (MOL), and back end of line (BEOL) layers. The frontside may face up during the manufacturing process and may be the primary surface for the device's operation. On the other hand, a backside of a semiconductor device may refer to a side that is opposite to where the main functional elements are located. The backside may be used for various supporting functions that complement the frontside. In some examples, the frontside may be opposite a substrate material on which the device was formed (e.g., opposite of a backside). In some examples, the backside may be a same side as a substrate material (e.g., a silicon substrate) on which the component was formed (e.g., a substrate for mechanical support during formation).

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a stack of memory dies, wherein each memory die of the stack is bonded with at least one other memory die of the stack;
a dielectric material in contact with a portion of a first memory die of the stack, the dielectric material extending beyond at least one lateral boundary of the first memory die of the stack; and
one or more molding materials formed over the stack of memory dies and over the dielectric material, the one or more molding materials spanning a lateral dimension of the dielectric material and in contact with a portion of at least one memory die of the stack.

2. The semiconductor device of claim 1, further comprising:
one or more second molding materials formed over the one or more molding materials.

3. The semiconductor device of claim 1, further comprising:
a plurality of contacts formed at a first surface of the first memory die of the stack, the plurality of contacts for making electrical connections with one or more other semiconductor dies.

4. The semiconductor device of claim 3, wherein the first memory die is bonded with a second memory die of the stack at a second surface of the first memory die that is opposite the first surface.

5. The semiconductor device of claim 1, further comprising:
a substrate bonded with a second memory die of the stack of memory dies, the second memory die located at an opposite end of the semiconductor device as the first memory die.

6. The semiconductor device of claim 1, wherein each memory die of the stack is bonded with at least one other memory die of the stack by a first plurality of contacts.

7. The semiconductor device of claim 1, wherein the stack of memory dies comprises three or more memory dies.

8. A method for manufacturing a semiconductor device, comprising:
bonding a respective first surface of a set of first memory dies to a carrier;
forming a dielectric material between and over each of the first memory dies and over the carrier, the dielectric material extending beyond respective lateral boundaries of each first memory die;
forming one or more stacks of memory dies above the set of first memory dies by bonding a set of second memory dies to respective second surfaces of the set of first memory dies opposite the respective first surfaces;
forming, after bonding the set of second memory dies, one or more molding materials between and over each stack of memory dies and over the dielectric material, the one or more molding materials spanning a lateral dimension of the dielectric material and in contact with a portion of at least one second memory die;
removing the carrier to expose the respective first surfaces of the first memory dies, the respective first surfaces comprising a plurality of contacts for making electrical connections with one or more other semiconductor dies; and
removing a portion of the one or more molding materials and a portion of the dielectric material, wherein each stack of memory dies is separated from other stacks of memory dies based at least in part on removing the portion of the one or more molding materials and the portion of the dielectric material.

9. The method of claim 8, further comprising:
bonding, after removing the portion of the one or more molding materials and the portion of the dielectric material, a first stack of the one or more stacks of memory dies with a substrate of a semiconductor die; and
forming one or more second molding materials over the one or more molding materials, the one or more second molding materials spanning a lateral dimension of the substrate and in contact with a portion of the dielectric material.

10. The method of claim 8, further comprising:
forming, after removing the carrier and before removing the portion of the one or more molding materials and the portion of the dielectric material, the plurality of contacts of the respective first surfaces with one or more conductive materials.

11. The method of claim 8, further comprising:
forming, after forming the dielectric material, a plurality of second contacts of the respective second surfaces with one or more conductive materials, wherein bonding the set of second memory dies to the respective second surfaces is based at least in part on forming the plurality of second contacts.

12. The method of claim 11, wherein bonding the set of second memory dies to the respective second surfaces comprises:
bonding the plurality of second contacts with a plurality of third contacts formed at a respective first surfaces of the set of second memory dies.

13. The method of claim 8, further comprising:
bonding, after forming the one or more molding materials, respective second surfaces of the set of second memory dies with a substrate to extend a height dimension of the semiconductor device.

14. The method of claim 8, further comprising:
determining that each first memory die of the set of first memory dies satisfies an evaluation procedure prior to bonding on the carrier.

15. A semiconductor device, comprising:
a first stack comprising a first plurality of memory dies, each memory die of the first stack bonded with at least one other memory die in the first stack;
a first dielectric material in contact with a portion of a first memory die of the first stack, the first dielectric material extending beyond each lateral boundary of the first memory die of the stack;
a second stack comprising a second plurality of memory dies, each memory die of the second stack bonded with at least one other memory die in the second stack, a first memory die of the second stack being bonded with a second memory die of the first stack; and
a second dielectric material in contact with a portion of the first memory die of the second stack, the second dielectric material extending beyond each lateral boundary of the first memory die of the second stack.

16. The semiconductor device of claim 15, further comprising:
one or more first molding materials formed over the first stack, the one or more first molding materials spanning a lateral dimension of the first dielectric material and in contact with a portion of at least one memory die of the first stack.

17. The semiconductor device of claim 16, further comprising:
one or more second molding materials formed over the second stack, the one or more second molding materials spanning a lateral dimension of the second dielectric material and in contact with a portion of at least one memory die of the second stack.

18. The semiconductor device of claim 17, further comprising:
one or more third molding materials formed between and over the first stack and the second stack, the one or more third molding materials in contact with the one or more first molding materials and the one or more second molding materials and extending beyond a lateral dimension of the first dielectric material and the second dielectric material.

19. The semiconductor device of claim 16, further comprising:
a third dielectric material formed over a surface of the second memory die of the first stack and over the one or more first molding materials, the third dielectric material spanning a lateral dimension of the one or more first molding materials.

20. The semiconductor device of claim 15, further comprising:
a plurality of contacts for making electrical connections, the plurality of contacts formed at a surface of the second memory die of the first stack, wherein a bond between the second stack and the first stack is formed using the plurality of contacts.

21. The semiconductor device of claim 15, further comprising:
a plurality of contacts for making electrical connections with one or more other semiconductor dies formed at a surface of the first memory die of the first stack.

22. A method for semiconductor manufacturing, comprising:
bonding a respective first surface of a first memory die to a carrier;
forming a first dielectric material over the first memory die and over the carrier, the first dielectric material extending beyond respective lateral boundaries of the first memory die;
bonding one or more second memory dies to a respective second surface of the first memory die to form a first stack of memory dies comprising the first memory die and the one or more second memory dies; and
bonding a second stack of third memory dies to the first stack of memory dies by bonding a respective third memory die of the second stack to a respective second memory die of the first stack, wherein a second dielectric material is formed over the respective third memory die and spans a lateral dimension of the respective third memory die.

23. The method of claim 22, further comprising:
forming, after bonding the one or more second memory dies, one or more first molding materials between and over the first memory die and the one or more second memory dies, the one or more first molding materials in contact with a portion of the first dielectric material and spanning a lateral dimension of the first dielectric material.

24. The method of claim 23, further comprising:
forming one or more second molding materials between and over each of the third memory dies of the second stack, the one or more second molding materials in contact with a portion of the second dielectric material and spanning a lateral dimension of the second dielectric material.

25. The method of claim 24, further comprising:
forming one or more third molding materials between and over the first stack and the second stack, the one or more third molding materials in contact with the one or more first molding materials and the one or more second molding materials and extending beyond a lateral dimension of the first dielectric material and the second dielectric material.

26. The method of claim 23, further comprising:
forming, prior to bonding the second stack of third memory dies, a third dielectric material over a second surface of a respective second memory die and over the one or more first molding materials, the third dielectric material in contact with a portion of the one or more first molding materials and spanning a lateral dimension of the one or more first molding materials; and
forming, at a second surface of the respective second memory dies, a plurality of contacts for making electrical connections with one or more other semiconductor dies, wherein bonding the second stack to the first stack is based at least in part on forming the plurality of contacts.

27. The method of claim 22, further comprising:
removing the carrier to expose the first surface of the first memory die; and
forming a plurality of contacts with one or more conductive materials at the first surface, the plurality of contacts for making electrical connections with one or more other semiconductor dies.

28. The method of claim 22, further comprising:
determining that the first memory die satisfies an evaluation procedure prior to bonding with the carrier, that the one or more second memory dies satisfy the evaluation procedure prior to bonding to the first memory die, and that each of the third memory dies satisfy the evaluation procedure prior to bonding with the first stack.

29. A semiconductor device, comprising:
a stack of memory dies, wherein each memory die of the stack is bonded with at least one other memory die of the stack;
a first dielectric material in contact with a portion of a first memory die of the stack, and the first dielectric material extending beyond each lateral boundary of the first memory die of the stack;
one or more first molding materials formed over the stack and over the first dielectric material, the one or more first molding materials spanning a lateral dimension of the first dielectric material and in contact with a portion of at least one memory die of the stack;
a logic die bonded with a first side of the first memory die opposite a second side of the first memory die, the logic die comprising circuitry operable to facilitate one or more access operations on the memory dies of the stack; and
one or more second molding materials formed over the first molding materials and over the logic die, the one or more second molding materials spanning a lateral dimension of the logic die.

30. The semiconductor device of claim 29, further comprising:
a plurality of contacts for making electrical connections formed at the first side of the first memory die, wherein the first memory die is bonded to the logic die by the plurality of contacts.
